(19) United States
(12) Patent Application Publication
(10) Pub. No.: US 2024/0379834 A1
(43) Pub. Date: Nov. 14, 2024

(54) RECESSED-GATE HIGH-ELECTRON-MOBILITY TRANSISTORS WITH DOPED BARRIERS AND ROUND GATE FOOT CORNERS

(71) Applicant: Teledyne Scientific & Imaging, LLC, Thousand Oaks, CA (US)

(72) Inventors: Keisuke Shinohara, Thousand Oaks, CA (US); Dean Regan, Simi Valley, CA (US); Casey King, Newbury Park, CA (US); Berinder Brar, Newbury Park, CA (US)

(21) Appl. No.: 18/660,342

(22) Filed: May 10, 2024

Related U.S. Application Data
(60) Provisional application No. 63/466,208, filed on May 12, 2023.

(51) Int. Cl. H01L 29/778; H01L 21/283; H01L 21/3065; H01L 29/20; H01L 29/24; H01L 29/423; H01L 29/66

(52) U.S. Cl. CPC H01L 29/778; H01L 29/42376; H01L 29/66431; H01L 21/283; H01L 21/3065; H01L 29/2003; H01L 29/24

(57) ABSTRACT

A high electron mobility transistor comprising a substrate. The substrate comprising: a buffer layer, a channel layer disposed on the buffer layer, an interlayer disposed on the channel layer, a spacer layer, and a first barrier layer between the spacer layer and a cap layer, the spacer layer is between the interlayer and the first barrier layer. The high electron mobility transistor comprises a source electrode disposed on the channel, a drain electrode disposed on the channel, and a gate electrode disposed between the source electrode and the drain electrode, the gate electrode defining a longitudinal portion extending through the capping layer, wherein a distal end of the longitudinal portion is in contact with the first barrier layer defines an external fillet between the distal end and the longitudinal portion.

### CROSS REFERENCE TO RELATED APPLICATIONS

The present application claims priority under 35 U.S.C. Section 119 (e) from Provisional Application 63/466,208, entitled “RECESSED-GATE HIGH-ELECTRON-MOBILITY TRANSISTORS WITH DOPED BARRIERS AND ROUND GATE FOOT CORNERS,” filed on May 12, 2023, the entire contents of each are incorporated herein by reference.

### FIELD

This disclosure relates generally to the field of field-effect transistors (FETs). In particular, this disclosure relates generally to high-electron-mobility transistors (HEMTs). More particularly, this disclosure relates generally to Gallium Nitride (GaN) and Gallium Oxide (Ga2O3) HEMTs.

### SUMMARY

In part, in one aspect, the disclosure relates to a high electron mobility transistor (HEMT). The HEMT comprises a substrate. The substrate comprises a buffer layer, a channel layer, an interlayer, a spacer layer, and a first barrier layer between the spacer layer and a cap layer. A source electrode is disposed on the channel. A drain electrode is disposed on the channel. A gate electrode is disposed between source electrode and drain electrode. The gate electrode defines a longitudinal portion extending through the capping layer. A distal end of the longitudinal portion is in contact with the first barrier layer defines an external fillet between the distal end and the longitudinal portion. In one aspect, the HEMT further comprises a second barrier layer in contact with the capping layer and the first barrier layer, wherein each of the first and second barrier layers are doped with silicon or germanium.

In one aspect, the first and second barrier layers include at least one semiconductor material selected from the group consisting of AlGaN, InAlN, ScAlN, InAlGaN, AlN, InN, or (AlGa) 203.

In one aspect, the first barrier layer has a first doping concentration defined as a two dimensional electron gas (2DEG) density in a source access region and a drain access region that is greater than the 2DEG induced by a maximum gate voltage under the distal end of the gate electrode.

In one aspect, the second barrier layer has a second doping concentration that is greater than a first density of an electron trap at a surface of the cap layer and greater than a second density of an electron trap at the cap layer and the second barrier layer interface. Any additional barrier layers are also doped.

In one aspect, the first barrier layer has a first doping concentration and the second barrier layer has a second doping concentration, wherein a maximum value for the first and second doping concentrations is set by an onset of parallel conduction through the first and second barrier layers.

In one aspect, the channel layer includes at least one semiconductor material selected from the group consisting of GaN, AlGaN, InGaN, InN, or Ga2O3.

In one aspect, the substrate further comprises an interlayer that includes an undoped AlN semiconductor material.

In one aspect, the substrate further includes a spacer layer that includes at least one semiconductor material selected from the group consisting of AlGaN, InAlN, ScAlN, InAlGaN, or (AlGa) 203.

In part, in one aspect, the disclosure relates to a method of fabricating a transistor. The method comprises growing on a substrate: a buffer layer, a channel layer, an interlayer, a spacer layer, a first barrier layer between the spacer layer and a cap layer, a source disposed on the channel layer, and a drain disposed on the channel layer. The method further comprises etching a recess into the cap layer through a portion of the first barrier layer to define an internal fillet edge in the first barrier layer; and depositing—a gate metal with an external fillet edge in the recess to extend above the capping layer.

In one aspect, etching comprises low-power reactive ion etching. In one aspect, etching comprises UV-assisted wet etching.

In one aspect, the method further comprises growing a second barrier layer on the first barrier layer.

In one aspect, the method further comprises doping the first barrier layer and the second barrier layer with silicon or germanium.

In one aspect, the method further comprises forming an ohmic contact with the source and channel layer using molecular beam epitaxy and forming an ohmic contact with the drain and channel layer using molecular beam epitaxy.

Although the disclosure relates to different aspects and embodiments, it is understood that the different aspects and embodiments disclosed herein can be integrated, combined, or used together as a combination system, or in part, as separate components, devices, and systems, as appropriate. Thus, each embodiment disclosed herein can be incorporated in each of the aspects to varying degrees as appropriate for a given implementation. Further, the various apparatus, optical elements, passivation coatings/layers, optical paths, waveguides, splitters, couplers, combiners, electro-optical devices, inputs, outputs, ports, channels, components and parts of the foregoing disclosed herein can be used comprising laser, laser-based communication system, waveguide, fiber, transmitter, transceiver, receiver, and other devices and systems without limitation.

These and other features of the applicant's teachings are set forth herein.

### BRIEF DESCRIPTION OF THE FIGURES

Unless specified otherwise, the accompanying drawings illustrate aspects of the innovations described herein. Referring to the drawings, wherein like numerals refer to like parts throughout the several views and this specification, several embodiments of presently disclosed principles are illustrated by way of example, and not by way of limitation. The drawings are not intended to be to scale. A more complete understanding of the disclosure may be realized by reference to the accompanying drawings in which:

FIG. 1 is a cross-sectional view of high-electron-mobility transistor (HEMT), according to an exemplary embodiment of the disclosure.

FIG. 2A is a cross-sectional view of a HEMT with a spacer layer, according to an exemplary embodiment of the disclosure.

FIG. 2B is a cross-sectional view of a HEMT with a spacer layer, according to an exemplary embodiment of the disclosure.

FIG. 3A is a cross-sectional view of a HEMT, according to an exemplary embodiment of the disclosure.

FIG. 3B is a cross-sectional view of a HEMT, according to an exemplary embodiment of the disclosure.

FIG. 4 is a graph of output characteristics for a 90-nm-gate HEMT, according to an exemplary embodiment of the disclosure.

FIG. 5 is a graph of transfer characteristics of a 90-nm-gate HEMT, according to an exemplary embodiment of the disclosure.

FIG. 6 is a graph of measured f_{T} and fₘₐₓ as a function of the gate length, according to an exemplary embodiment of the disclosure.

FIG. 7 is a graph of fₘₐₓ as a function of drain current density, according to an exemplary embodiment of the disclosure.

FIG. 8 is a graph of knee current densities as a function of a quiescent drain voltage, at an off-state V_{g.q}=Vₜₕ−2V, according to an exemplary embodiment of the disclosure.

FIG. 9 is a graph of the w- and load-pull characteristics, according to an exemplary embodiment of the disclosure.

FIG. 10 is a graph of the power output, according to an exemplary embodiment of the disclosure

FIG. 11 is a graph of the power efficiency, according to an exemplary embodiment of the disclosure.

FIG. 12 is a conventional mini field plate.

FIG. 13 is a conventional N-polar HEMT.

FIG. 14 is a conventional ScAlN HEMT.

FIG. 15 is a conventional AlN HEMT.

FIG. 16 is a method of manufacturing a GaN HEMT transistor, according to an exemplary embodiment of this disclosure.

### DETAILED DESCRIPTION

A high-electron-mobility transistor (HEMT), also known as heterostructure FET or modulation-doped FET, is a field-effect transistor incorporating a junction between two materials with different band gaps as the channel instead of a doped region.

This disclosure generally provides various embodiments of recessed-gate GaN-HEMTs with doped barrier layers. Dynamic current collapse limits output power and efficiency performance of GaN HEMTs. This limitation originates from electron trapping effect at the surface of the cap layer and interfaces of the cap layer and the barrier layer epitaxial structure. Output power and other limitations become more prominent when GaN HEMTs are scaled for higher frequency operation.

Next-generation millimeter-wave radio frequency (RF) systems require higher efficiency, output power, linearity, and wider bandwidth. These parameters, however, are in a trade-off relationship that becomes more prominent as operational frequencies increase due to the narrower design window and increased parasitic effects on the frequency performance for millimeter-wave transistors, as compared to microwave transistors. This disclosure provides various embodiments of epitaxial and gate configurations for deeply-scaled AlGaN/GaN HEMTs targeting W-band applications.

As the frequency of operation increases, the dimension of the device, including epitaxial layer thicknesses, source-to-drain distance (L_{sd}), gate length (L_{g}), field plate length, and dielectric thicknesses of the field plate(s), are proportionally reduced by 1/frequency to maintain proper electrostatics. In addition, parasitic resistances and capacitances, including gate fringing capacitances, have a more significant impact on the frequency performance of the transistors, thus limiting their gain and efficiency, especially at W-band frequencies and above. The reduction in size and increase in parasitic effects constrain the device design window as well as the fabrication process window, thereby making it harder to co-optimize frequency, output power, and efficiency performance.

In one aspect, this disclosure provides various embodiments of GaN-HEMTs configured for low-noise and power amplifier (PA) applications at W-band frequencies. In various aspects, this disclosure provides various embodiments of GaN HEMTs configured for PA applications at high frequencies such as W-band and higher. The epitaxial structure that includes, from bottom to top, a GaN buffer layer, a GaN (or AlGaN) channel layer, an AlN interlayer, an AlGaN (or InAlN, ScAlN, InAlGaN) spacer layer, Si (or Ge) doped AldaN (or InAlN, ScAlN, InAlGaN) barrier layers, and a GaN cap layer, is grown on a SiC, Si, or sapphire substrate. The doped barrier layers are recess etched only under the gate foot whose corner is round-shaped. The gate foot is the distal end of the longitudinal gate portion extending into the epitaxial structure. In various embodiments, the gate foot defines an external fillet, which may be referred to herein as a gate with round gate foot corner, for example. A combination of the doped barrier epitaxial structure and the round corner gate foot structure enables a high-frequency power performance with (1) suppressed dynamic knee current collapse, (2) high power density, (3) high power added efficiency (PAE), and (4) high gain linearity. The various configurations of the GaN HEMTs disclosed herein also are beneficial for RF switch applications where low insertion loss, wide bandwidth, and high switching speed are often required.

In one general aspect, two or more than two Si-doped AlGaN barrier layers are grown on an undoped AlN interlayer and an undoped AlGaN spacer layer. The Si doping concentration in the lower AlGaN layer (Nsi1) is selected so that the two dimensional electron gas (2DEG) density in the source and drain access regions is higher than the 2DEG induced by the maximum gate voltage under the gate foot. The Si doping concentration in the upper AlGaN layer (Nsi2) is selected to be higher than densities of electron traps at the surface and GaNon-AlGaN interface. The maximum values for Nsi1 and Nsi2 are set by the onset of parallel conduction through the AlGaN barrier layers. The round gate foot corner alleviates the peak electric field without a need for a nano-field plate.

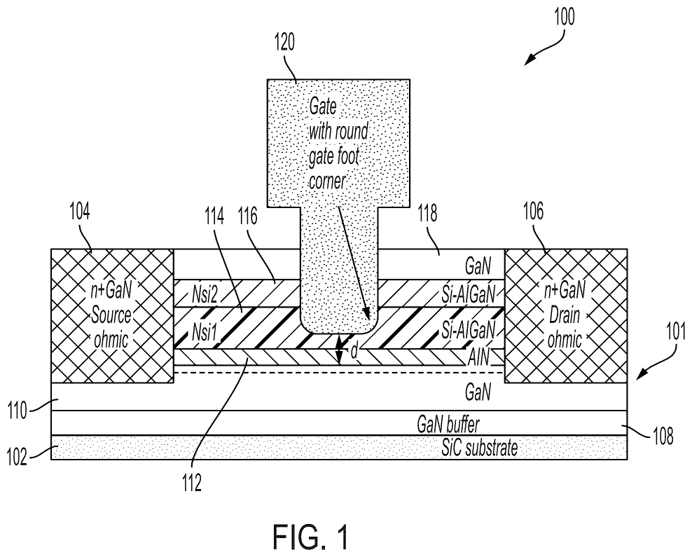

FIG. 1 is a cross-sectional view of an HEMT, according to an exemplary embodiment of the disclosure. The HEMT 100 comprises a substrate 101, a source electrode 104 disposed on the substrate 101, and a drain electrode 106 disposed on the substrate 101. The substrate 101 comprises a channel layer 110 disposed on the buffer layer 108, an interlayer 112 disposed on the channel layer 110 and a first barrier layer 114 between the channel layer 110 and the capping layer 118. The HEMT 100 further comprises a gate electrode 120 disposed between the source electrode 104 and drain electrode 106. The gate electrode 120 defines a longitudinal portion extending through the capping layer 118. A distal end of the longitudinal portion is in contact with the first barrier layer 114 and defines an external fillet (round gate foot corner) between the distal end and the longitudinal portion.

As shown in FIG. 1, the HEMT 100 comprises, from the bottom up, the buffer layer 108, the channel layer 110, the interlayer 112, the first barrier layer 114, the second barrier layer 116, and the capping layer 118. In one aspect, there can be more than two barrier layers 114, 116. The layers 114, 116 are formed on a substrate 102. The substrate 102 comprises SiC, Si, or sapphire. As shown, the layers of the substrate 101 are formed on the SiC substrate 102.

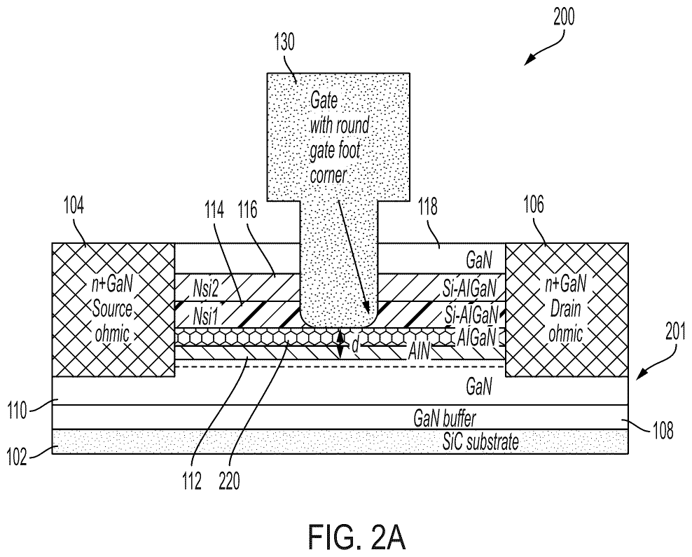

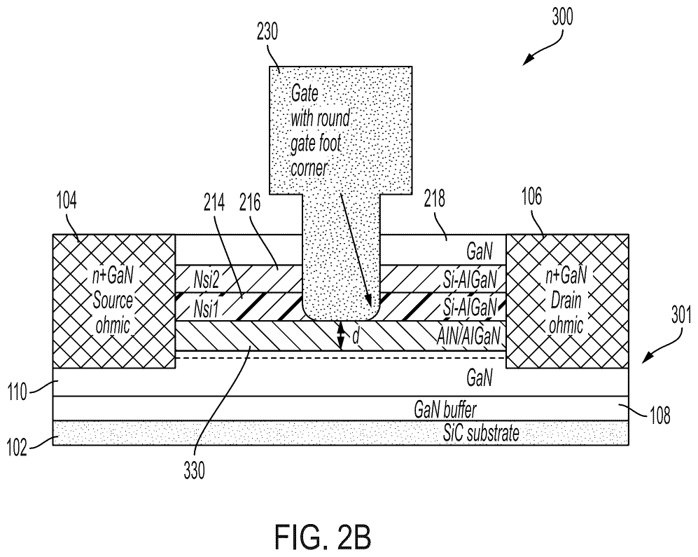

For example, the epitaxial structure comprises, from bottom to top, a GaN buffer layer 108, a GaN (or AlGaN) channel layer 110, an AlN interlayer 112, an AlGaN (or InAlN, ScAlN, InAlGaN) spacer layer (optionally and shown in FIG. 2), Si (or Ge) doped AlGaN (or InAlN, ScAlN, InAlGaN) barrier layers 114, 116, and a GaN cap layer 118, and is grown on a SiC, Si, or sapphire substrate 102.

In one aspect, the HEMT 100 further comprises a second barrier layer 116 in contact with the capping layer 118 and the first barrier layer 114. Each of the first 114 and second 116 barrier layers are doped with silicon or germanium.

In one aspect, the substrate 101 further comprises an interlayer 112 that includes an undoped AlN semiconductor material. The interlayer 112 is shown in FIG. 1 as layer AlN.

FIG. 2A is a cross-sectional view of an HEMT 200 with a spacer layer, according to an exemplary embodiment of the disclosure. The HEMT 200 comprises, from the bottom up, the buffer layer 108, the channel layer 110, the interlayer 112, the spacer layer 222, the first barrier layer 114, the second barrier layer 116, and the capping layer 118. In one aspect, there can be more than two barrier layers 114, 116. FIG. 2 is similar to FIG. 1. For brevity like reference numbers are the same and operate in a similar manner.

In one aspect, the substrate 201 further comprises an interlayer 112 that includes an undoped AlN semiconductor material. The interlayer 112 is shown in FIG. 2 as the AlN layer. The substrate 201 further includes a spacer layer 222, shown as AlGaN, that includes at least one semiconductor material selected from the group consisting of AlGaN, InAlN, ScAlN, or InAlGaN.

FIG. 2B is a cross-sectional view of an HEMT 300 with a spacer layer 330, according to an exemplary embodiment of the disclosure. FIG. 2B is substantially the same as FIG. 2. Like reference numbers are not described for brevity. The interlayer is shown with the optional spacer layer as a single layer 330.

To eliminate the current bottleneck in access regions,

$$\frac{ε}{d} ( {V}_{max} - {V}_{p} ) \leq {N}_{pol} + Nsi 1.$$

For example, the density of surface or interface traps is less than or equal to the Si doping concentration (Nsi2) of the second layer 116. This suppresses electron trapping in the access regions.

For example, the Si doping concentrations of either the first layer 114 or the second layer 114 is less than the onset of parallel conduction in the AlGaN barrier (single layer 330).

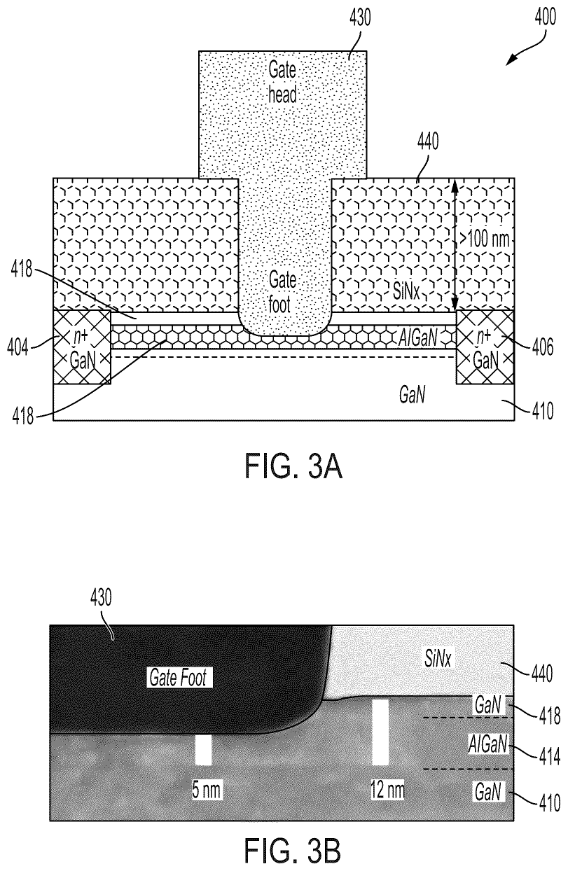

FIG. 3A is a cross-sectional view of an HEMT 400, according to an exemplary embodiment of the disclosure. FIG. 3B is a cross-sectional view of an HEMT 400, according to an exemplary embodiment of the disclosure. The HEMT 400 comprises a substrate 401, a source electrode 44 disposed on the substrate, and a drain electrode 46 disposed on the substrate.

The substrate 401 comprises a channel layer 410 (GaN), a capping layer 418, and a first barrier layer (AlGaN) 414 between the channel layer 410 and the capping layer 418.

The HEMT 400 further comprises a gate electrode 430 defining a longitudinal portion extending through the capping layer 418. A distal end of the longitudinal portion is in contact with the first barrier layer 414 and defines an external fillet between the distal end and the longitudinal portion.

In one aspect, the total thickness of the GaN cap 418 and AlGaN barrier layers 414 is 12 nm and can be selected in a suitable range of 10 to 40 nm. The AlGaN barrier 414 thickness under the gate electrode is reduced to 5 nm or a range from 2 to 10 nm. A recess is formed in the capping layer 418 and through a portion of the barrier layer 414. The recess may be formed through gate recess etching using low-power reactive ion etching (RIE), to maintain a high gate-to-channel aspect ratio of greater than 10 (Lg/d, where d is the gate-to-channel distance) for short Lg of >50 nm.

Referring now to FIGS. 1-3, in one aspect, the first 114, 414 and second 116 barrier layers include at least one semiconductor material selected from the group consisting of AlGaN, InAlN, ScAlN, InAlGaN, AlN, InN, or (AlGa) 203. The first barrier layer 114, 414 has a first doping concentration defined as a 2DEG density in a source access region and a drain access region that is greater than the 2DEG induced by a maximum gate voltage under the gate electrode 130, 430. The second barrier layer 116 has a second doping concentration that is greater than a sum of a first density of an electron trap at a surface of the cap layer 118, 418 and greater than a second density of an electron trap at GaNon-AlGaN interface. The first barrier layer 114, 414 has a first doping concentration and the second barrier layer 116 has a second doping concentration, wherein a maximum value for the first and second doping concentrations is set by an onset of parallel conduction through the first 114, 414 and second 116, 216 barrier layers. The minimum value of NSi2 is determined by NSi2<a sum of trap densities at the GaN cap surface and the GaN-on-AlGaN interface. In one aspect, there are additional barrier layers disposed between the first 114, 414 and second 116 barrier layers.

In one aspect, the HEMT 100, 200, 300, 400 may further comprise a second barrier layer 11 in contact with the cap layer 118, 418 and the first barrier layer 114, 414. Each of the first 114, 414 and second 116 barrier layers are doped with either silicon or germanium. The additional barrier layers are similar in structure in to the first 114, 414 and second 116 barrier layers.

In one aspect, the channel layer 110, 410 includes at least one semiconductor material selected from the group consisting of GaN or AlGaN.

For example, the measured nₛ and electron mobility are 1.3×1013 cm-2 and 1900 cm2/V·s, respectively. The n+GaN ohmic contacts are formed using MBE regrowth, with a low access resistance (R_{ac}) of 0.1 Ω·mm from an ohmic metal to the n+GaN/2DEG interface (the interface between 2DEG and the drain and the interface between 2DEG and the source).

In one aspect, the barrier layer is doped with Si to: (i) passivate donor-like trap states that exist at the GaN-on-AlGaN interface to reduce electron trapping effects, and (ii) increase the 2DEG density (nₛ) in the channel layer through the modulation doping to increase transistor current density. In general, the GaN-on-AlGaN interface is the interface between the second barrier layer 116 and the cap layer 118.

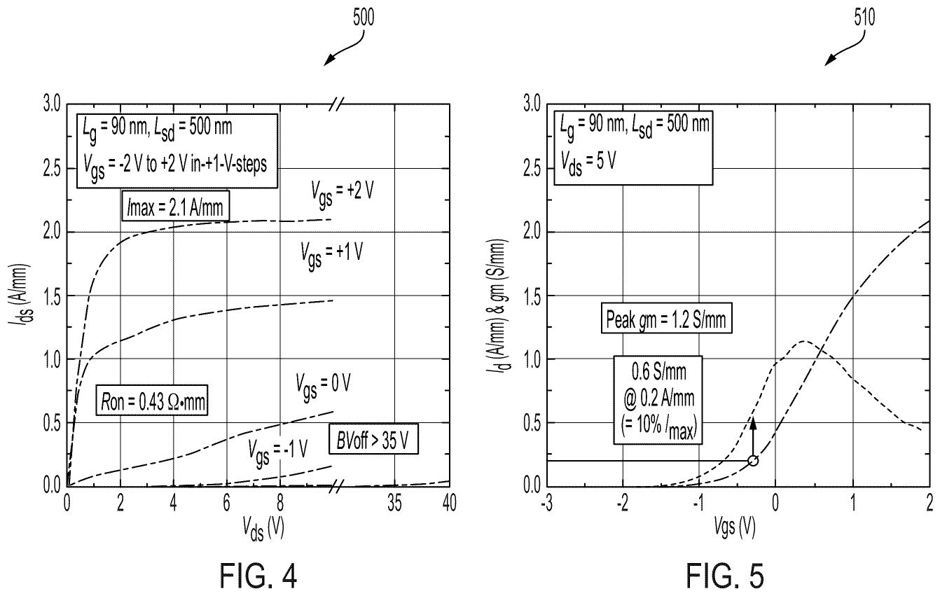

FIG. 4 is a graph 500 of output characteristics for a 90 nm-gate HEMT, according to an exemplary embodiment of the disclosure. FIG. 5 is a graph 510 of transfer characteristics of a 90 nm-gate HEMT, according to an exemplary embodiment of the disclosure. As shown in FIGS. 4 and 5, the 90 nm-gate device, with an L_{sd} of 500 nm, exhibits a maximum drain current density exceeding 2 A/mm, with an on-resistance (Rₒₙ) of 0.43 Ω·mm and a peak gm of 1.2 S/mm.

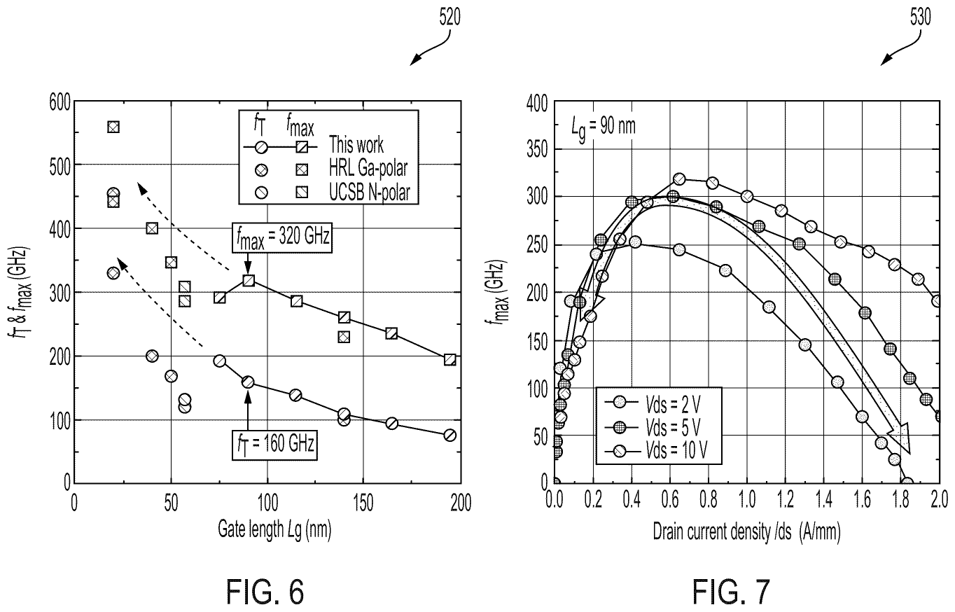

FIG. 6 is a graph 520 of measured f_{T} and fₘₐₓ as a function of the gate length, according to an exemplary embodiment of the disclosure. Measured f_{T} and fₘₐₓ exhibit good scaling behavior with Lg.

FIG. 7 is a graph 530 of fₘₐₓ as a function of drain current density, according to an exemplary embodiment of the disclosure. The 90 nm gate device also exhibits high power gain (fₘₐₓ) in the broad Ids range along the load line, with a peak value of 320 GHz at around class-AB bias conditions.

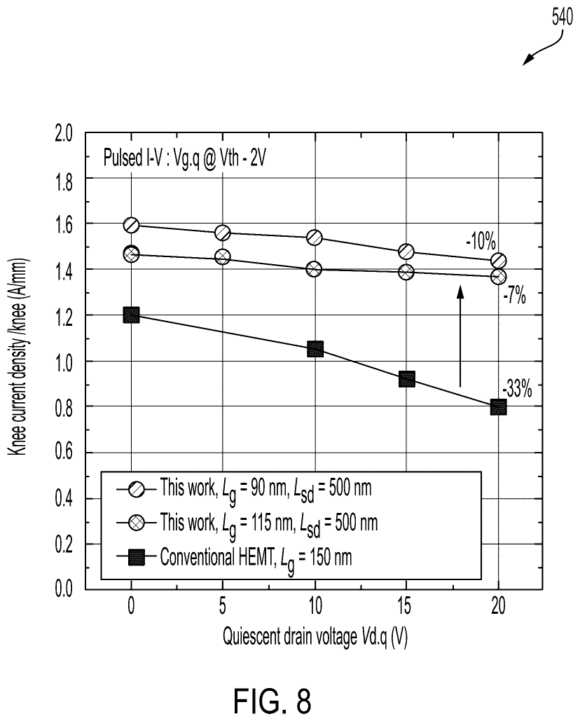

FIG. 8 is a graph 540 of knee current densities as a function of a quiescent drain voltage, at an off-state V_{g.q}=Vₜₕ−2V, according to an exemplary embodiment of the disclosure. The knee current collapse is less than 10% at a quiescent drain voltage of 20V, compared to the conventional 150-nm T-gate GaN HEMTs, without requiring an additional field plate structure. Dynamic current collapse is a common problem that limits output power and efficiency performance of GaN HEMTs. The problem originates from electron trapping effect at the surface and interfaces in the GaN HEMT epitaxial structure. The problem becomes more prominent when GaN HEMTs are scaled for higher frequency operation. FIG. 8 illustrates how the HEMT of this disclosure improves (reduces) the current collapse in GaN HEMTs.

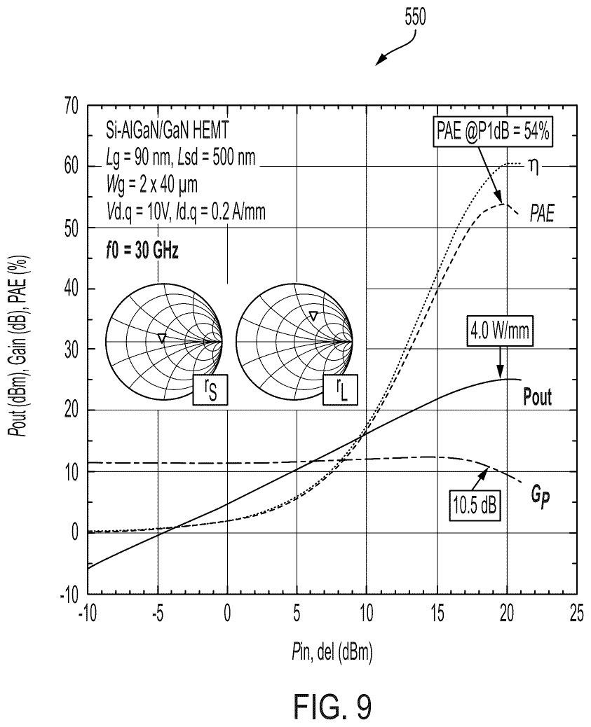

FIG. 9 is a graph 550 of the W and load-pull characteristics, according to an exemplary embodiment of the disclosure. This graph illustrates the different characteristics of the HEMT of this disclosure. The Pour is 4 W/mm at V_{d.q}=10V. The peak PAE is 54%.

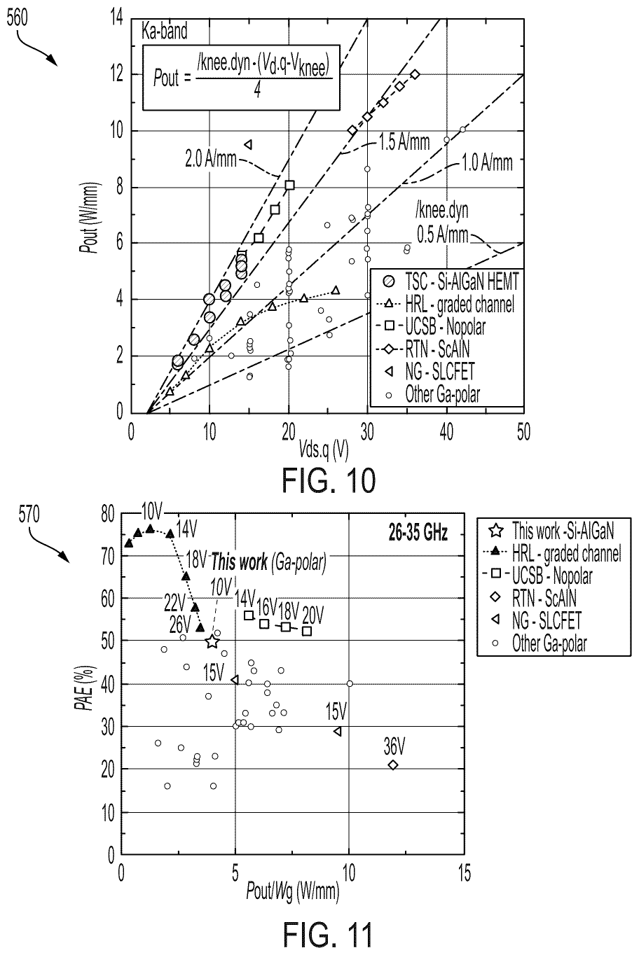

FIG. 10 is a graph 560 of the power output, according to an exemplary embodiment of the disclosure. FIG. 11 is a graph 570 of the power added efficiency, according to an exemplary embodiment of the disclosure. The stars illustrate this HEMT of this disclosure.

These device characteristics shown in FIGS. 4-11 are important in low-noise and power amplifiers at W-band frequencies. These co-optimized epi/device structures and simple fabrication process ensure reliable and manufacturable GaN HEMT technology.

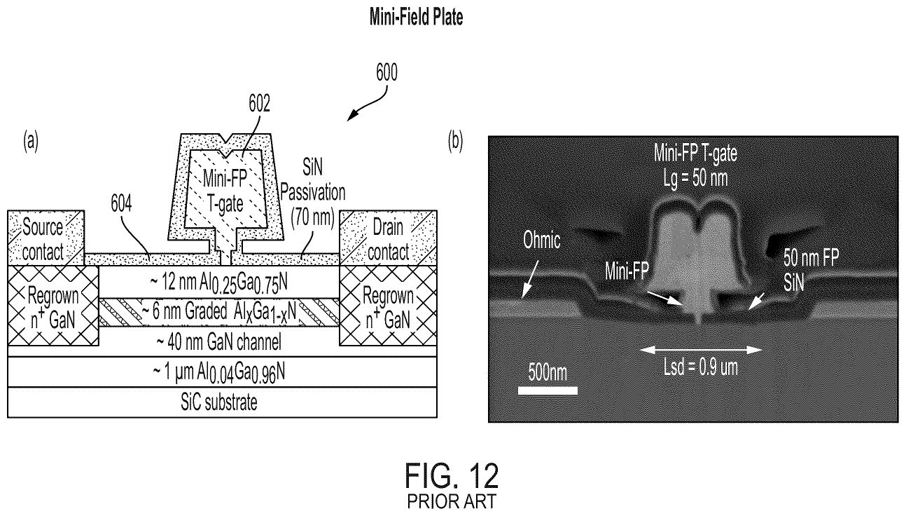

FIG. 12 is a conventional mini field plate 600. The mini field plate 600 in 12 (a) comprises a mini field plate (FPT) gate electrode 602 that extends only through the top layer of SiN 604. The gate electrode 602 does not extend through the layers formed on the substrate. The mini-field plate 600 comprises a single barrier layer without Si or Ge doping.

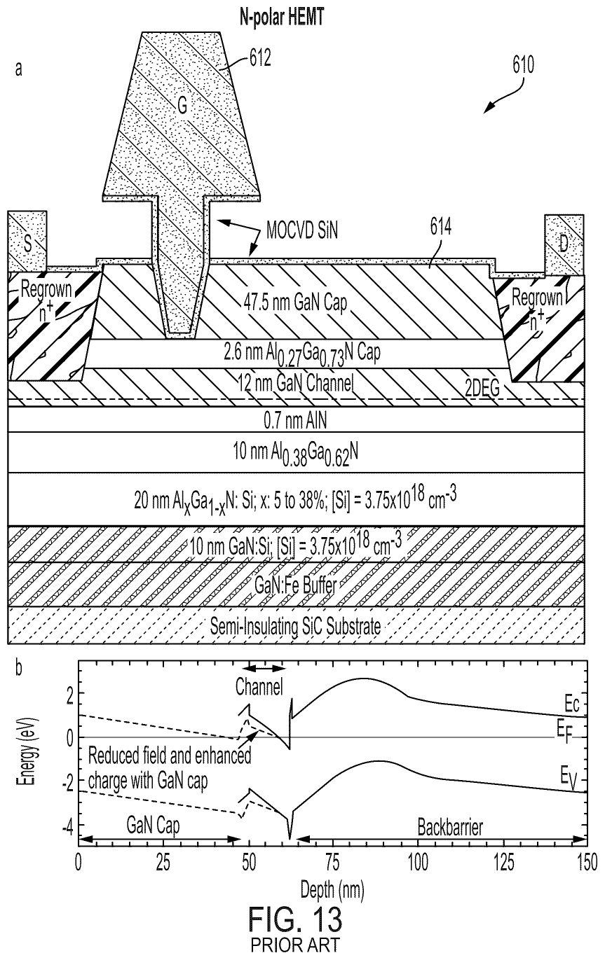

FIG. 13 is a conventional N-polar HEMT 610. The N-polar HEMT 610 comprises a gate electrode 612 that extends through a portion of the capping layer 614. The N-polar HEMT 610 does not comprise a barrier layer doped with Si or Ge.

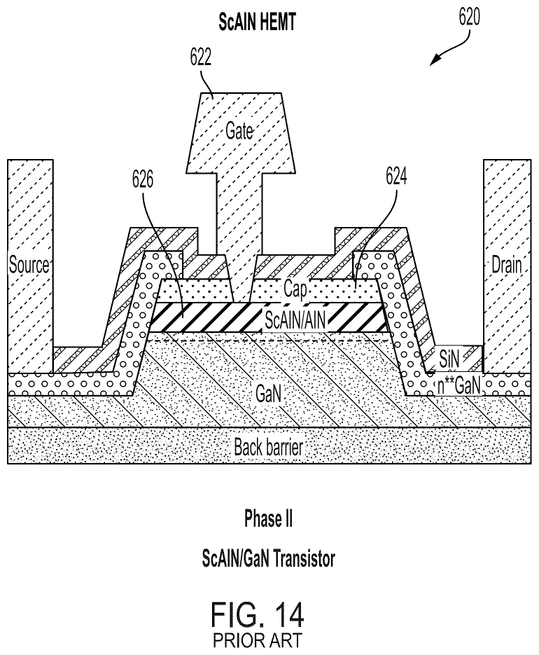

FIG. 14 is a conventional ScAlN HEMT 620. The ScAlN HEMT 620 comprises a gate electrode 622 that extends through the capping layer 624 to a single barrier layer. The barrier layer 626 comprises ScAlN/AlN, without Si or Ge doped barrier layer.

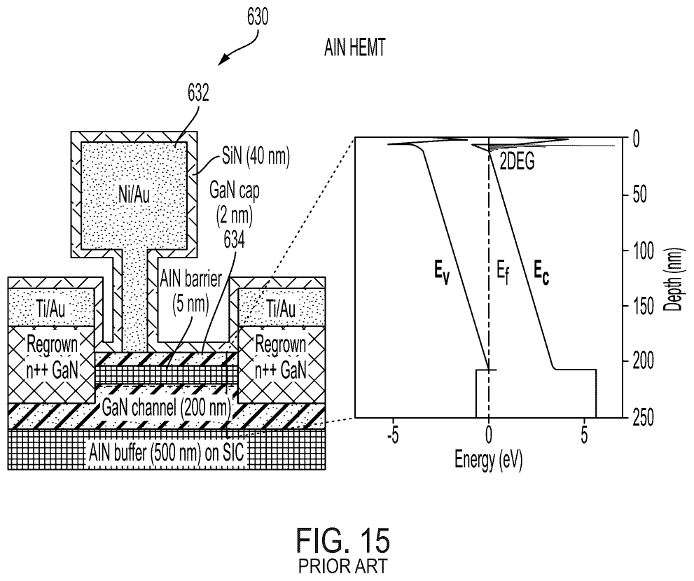

FIG. 15 is a conventional AlN HEMT 630. The AlN HEMT 630 comprises a gate electrode 632 that contacts the capping layer 634 and does not extend through the capping layer 634. The AlN also comprises a single barrier layer, without Si or Ge doping.

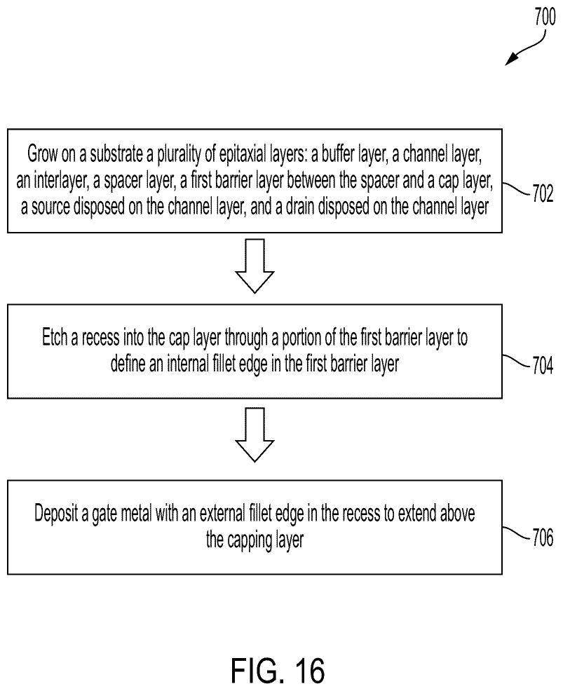

FIG. 16 is a method 700 of manufacturing a GaN HEMT transistor, according to an exemplary embodiment of this disclosure. The method 700 may be implemented to manufacture any of the HEMTs 100, 200, 300, 400 of FIGS. 1-3. The method 700 of fabricating a transistor comprises growing 702 on a substrate: a buffer layer, a channel layer, an interlayer, a spacer layer, a first barrier layer between the channel layer and a cap layer, a source disposed on the channel layer, and a drain disposed on the channel layer.

The method 700 further comprises etching 704 a recess into the cap layer through a portion of the first barrier layer to define an internal fillet edge in the first barrier layer and depositing 706 a gate metal with an external fillet edge in the recess to extend above the cap layer.

In one aspect, etching 706 comprises low-power reactive ion etching. The gate with round corners is formed through gate recess RIE process optimization, which helps alleviate the electric field under large signal operation. The combination of the epitaxial design and the gate structure enables greatly reduced knee current collapse.

In one aspect, etching 706 comprises UV-assisted wet etching.

In one aspect, the method further comprises growing a second barrier layer on the first barrier layer.

In one aspect, the method further comprises doping the first barrier layer and the second barrier layer with silicon or germanium.

In one aspect, the method further comprises forming an ohmic contact with the source and channel layer using molecular beam epitaxy and forming an ohmic contact with the drain and channel layer using molecular beam epitaxy.

Although the various embodiments were described as AlGaN/GaN HEMTs configurations, the techniques described herein can be applied to any kinds of GaN-based HEMTs made of any kinds of semiconductor materials such as (In)(Al)(Ga)N/(Al)GaN, ScAlN/(Al)GaN, (AlGa)2O3/Ga2O3 HEMT material systems. The techniques described herein are applicable to a wide range of RF products from power amplifiers, low-noise amplifiers, to low-loss RF switches.

The techniques described in accordance with the present disclosure can be applied to a wide range of RF products, including (1) reliable power amplifiers with an unprecedented combination of output power, efficiency, linearity, (2) Robust low-noise amplifiers with high linearity, (3) Low insertion-loss RF switches with high isolation and power handling capability. This disclosure can be applied to power amplifier monolithic microwave integrated circuits (MMICs) with high output power, high efficiency, high linearity with high reliability at Ka-band to W-band and even D-band, RF switch MMICs with a low insertion loss and high switching speed, and low noise amplifier MMICs with high input power survivability.

The device structure described in this disclosure can be implemented without increasing fabrication cost from the conventional fabrication process.

Having thus described several aspects and embodiments of the technology of this application, it is to be appreciated that various alterations, modifications, and improvements will readily occur to those of ordinary skill in the art. Such alterations, modifications, and improvements are intended to be within the scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more than one method. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more than one of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately” and “about” may be used to mean within +20% of a target value in some embodiments, within +10% of a target value in some embodiments, within +5% of a target value in some embodiments, and yet within +2% of a target value in some embodiments. The terms “approximately” and “about” may include the target value.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. The transitional phrases “consisting of” and “consisting essentially of” shall be closed or semi-closed transitional phrases, respectively.

Where a range or list of values is provided, each intervening value between the upper and lower limits of that range or list of values is individually contemplated and is encompassed within the disclosure as if each value were specifically enumerated herein. In addition, smaller ranges between and including the upper and lower limits of a given range are contemplated and encompassed within the disclosure. The listing of exemplary values or ranges is not a disclaimer of other values or ranges between and including the upper and lower limits of a given range.

The use of headings and sections in the application is not meant to limit the disclosure; each section can apply to any aspect, embodiment, or feature of the disclosure. Only those claims which use the words “means for” are intended to be interpreted under 35 USC 112 (f). Absent a recital of “means for” in the claims, such claims should not be construed under 35 USC 112. Limitations from the specification are not intended to be read into any claims, unless such limitations are expressly included in the claims.

Embodiments disclosed herein may be embodied as a system, method or computer program product. Accordingly, embodiments may take the form of an entirely hardware embodiment, an entirely software embodiment (including firmware, resident software, micro-code, etc.) or an embodiment combining software and hardware aspects that may all generally be referred to herein as a “circuit,” “module,” or “system.” Furthermore, embodiments may take the form of a computer program product embodied in one or more computer readable medium(s) having computer readable program code embodied thereon.

References: [1] L. Shen, et al., “Deep-recessed GaN HEMTs using selective etch technology exhibiting high microwave performance without surface passivation,” IEEE International Microwave symposium, June 2007.

What is claimed is:

1. A high electron mobility transistor comprising:
a substrate comprising:
a buffer layer;
a channel layer disposed on the buffer layer;
an interlayer disposed on the channel layer; and
a first barrier layer between the interlayer and a cap layer;
a source electrode disposed on the channel layer;
a drain electrode disposed on the channel layer; and
a gate electrode disposed between the source electrode and the drain electrode, the gate electrode defining a longitudinal portion extending through the capping layer, wherein a distal end of the longitudinal portion is in contact with the first barrier layer defines an external fillet between the distal end and the longitudinal portion.

2. The transistor of claim 1, further comprising a spacer layer between the interlayer and the first barrier layer.

3. The transistor of claim 2, further comprising a second barrier layer in contact with the capping layer and the first barrier layer, wherein each of the first and second barrier layers are doped with silicon or germanium.

4. The transistor of claim 3, wherein the first and second barrier layers are doped with at least one of Silicon or Germanium.

5. The transistor of claim 3, wherein the first and second barrier layers include at least one semiconductor material selected from the group consisting of AlGaN, InAlN, ScAlN, InAlGaN, AlN, InN, or (AlGa) 203.

6. The transistor of claim 5, wherein the first barrier layer has a first doping concentration defined as a two dimensional electron gas (2DEG) density in a source access region and a drain access region that is greater than the 2DEG induced by a maximum gate voltage under the distal end of the gate electrode.

7. The transistor of claim 5, wherein the second barrier layer has a second doping concentration that is greater than a first density of an electron trap at a surface of the cap layer and greater than a second density of an electron trap at an interface of the cap layer and the second barrier layer.

8. The transistor of claim 5, wherein the first barrier layer has a first doping concentration and the second barrier layer has a second doping concentration, wherein a maximum value for the first and second doping concentrations is set by an onset of parallel conduction through the first and second barrier layers.

9. The transistor of claim 1, wherein the channel layer includes at least one semiconductor material selected from the group consisting of GaN, AlGaN, InGaN, InN, or Ga2O3.

10. The transistor of claim 1, wherein the substrate further comprises an interlayer that includes an undoped AlN semiconductor material.

11. The transistor of claim 1, wherein the substrate further includes a spacer layer that includes at least one semiconductor material selected from the group consisting of AlGaN, InAlN, ScAlN, InAlGaN, or (AlGa) 203.

12. The transistor of claim 1, defining a distance between a distal end of the gate electrode and the distal end of the first barrier layer is in a range from 2 to 10 nm.

13. The transistor of claim 1, defining a thickness of the cap layer and the first barrier layer to be in a range of 10 to 40 nm.

14. The transistor of claim 3, defining a thickness of the cap layer, the first barrier layer, and the second barrier layer to be in a range of 10 to 40 nm.

15. A method of fabricating a transistor, the method comprising:
growing on a substrate a plurality of epitaxial layers comprising:
a buffer layer;
a channel layer;
an interlayer;
a spacer layer;
a first barrier layer between the spacer layer and a cap layer;
a source disposed on the channel layer; and
a drain disposed on the channel layer;
etching a recess into the cap layer through a portion of the first barrier layer to define an internal fillet edge in the first barrier layer; and
depositing a gate metal with an external fillet edge in the recess to extend above the capping layer.

16. The method of claim 15, wherein etching comprises low-power reactive ion etching.

17. The method of claim 15, further comprising growing a second barrier layer on the first barrier layer.

18. The method of claim 15, wherein etching comprises UV-assisted wet etching.

19. The method of claim 17, further comprising doping the first barrier layer and the second barrier layer with silicon or germanium.

20. The method of claim 15, further comprising:
forming an ohmic contact with the source and channel layer using molecular beam epitaxy; and
forming an ohmic contact with the drain and channel layer using molecular beam epitaxy.
